(19) United States
(12) Patent Application Publication
(10) Pub. No.: US 2019/0153595 A1
(43) Pub. Date: May 23, 2019

(54) C-AXIS ALIGNED CRYSTALLINE IGZO THIN FILM AND MANUFACTURE METHOD THEREOF

(71) Applicant: Wuhan China Star Optoelectronics Technology Co., Ltd., Wuhan City (CN)

(72) Inventor: Xuanyun Wang, Wuhan City (CN)

(21) Appl. No.: 15/505,107

(22) PCT Filed: Dec. 28, 2016
(86) PCT No.: PCT/CN2016/112524

§ 371 Date: Feb. 20, 2017

(30) Foreign Application Priority Data
Dec. 13, 2016 (CN) 201611147744.1

(51) Int. Cl. C23C 16/40; C23C 16/455; H01L 27/12; H01L 21/02

(52) U.S. Cl. CPC C23C 16/407; C23C 16/45529; C23C 16/45544; H01L 27/1262; H01L 21/02609; H01L 21/02565; H01L 21/0262; H01L 27/1225

(57) ABSTRACT

The present invention provides a C-axis Aligned Crystalline IGZO thin film and a manufacture method thereof. In the manufacture method of the C-axis Aligned Crystalline IGZO thin film of the present invention, by utilizing the method of atomic layer deposition to manufacture the C-axis Aligned Crystalline IGZO thin film, the structure of the C-axis Aligned Crystalline IGZO can be accurately controlled in the atomic level, and the crystalline quality of the C-axis Aligned Crystalline IGZO is fine, and the oxygen defect is less, which can raise the stability of TFT; moreover, the area of the crystalline region in the C-axis Aligned Crystalline IGZO thin film is larger, which reaches up for micron level to millimeter level, and thus can promote the large scale application of the C-axis Aligned Crystalline IGZO; meanwhile, the present invention utilizes the optimized process condition to manufacture the C-axis Aligned Crystalline IGZO thin film.

### FIELD OF THE INVENTION

The present invention relates to a display technology field, and more particularly to a C-axis Aligned Crystalline IGZO thin film and a manufacture method thereof.

### BACKGROUND OF THE INVENTION

The Thin Film Transistor (TFT) is a main drive component in a Liquid Crystal Display (LCD) and an Active Matrix Organic Light-Emitting Diode (AMOLED) at present, and directly relates to the development direction of the high performance flat panel display device.

With the rising of the terminal applications of smart phone and the tablet display, the high precision panel requirements over 250 PPI (Pixels Per Inch) gradually become tie-in trend, and more panel factories are urged to expand the production of the high precision Low Temperature Poly Silicon (LTPS) Thin Film Transistor. However, the manufacture process of the Low Temperature Poly Silicon Thin Film Transistor (LTPS TFT) production line is extremely complicated, and the yield is a major problem, too. Thus, the panel factories actively involved in the research and development of the metal oxide semiconductor. At present, the amorphous Indium Gallium Zinc Oxide (a-IGZO) technology is more mature.

IGZO is an abbreviation of Indium Gallium Zinc Oxide. It is a thin film transistor technology to form a layer of metal oxide on the active layer of the TFT-LCD. IGZO technology is controlled by Sharp, and a product which is developed together with the Japan semiconductor energy research institute. Except Sharp, Samsung SDI and LG display also possess the capabilities of producing the IGZO panel.

Comparing the IGZO with the amorphous silicon (a-Si) material, the electron mobility is 20 to 50 times faster than the a-Si TFT. IGZO uses the indium, gallium, zinc, oxygen to replace the present pattern layer of the traditional a-Si, which can significantly shorten the response duration of the screen, and reduce the size of the transistor, and raise the aperture ratio of the panel pixel, and realize the high precision more easily. Besides, the simple external circuit can be integrated into the panel, and the mobile device is lighter and thinner, and the power consumption drops to ⅔ than before.

The biggest issue existing in the IGZO large scale use is that the rapid change of the vacancy oxygen (or oxygen defect) in IGZO will lead to the worse stability of TFT. This is an issue caused by the defect of the IGZO material itself. As wanting to solve this issue, it must control the change of the vacancy oxygen from the point of the structure of the material itself for promoting the stability of TFT. C-axis Aligned Crystalline (CAAC) IGZO has the layered crystalline structure, no grain boundary. The oxygen defects of the material itself are very few, and it has the incomparable advantage in terms of TFT stability. The research team of Semiconductor Energy Laboratory Co., Ltd uses the magnetron sputtering method to manufacture the C-axis Aligned Crystalline IGZO thin film. However, the manufactured C-axis Aligned Crystalline IGZO thin film only has an area, of which the diameter is 1 nm-3 nm is in the crystalline state, and most of the area is in the amorphous state. Namely, in the C-axis Aligned Crystalline IGZO thin film, only a very small area is C-axis Aligned Crystalline IGZO, the rest of the area is a-IGZO. Because the area of the crystalline region is smaller, thus it is disadvantageous to the large scale application of the C-axis Aligned Crystalline IGZO.

### SUMMARY OF THE INVENTION

An objective of the present invention is to provide a manufacture method of a C-axis Aligned Crystalline IGZO thin film. The crystalline quality of the C-axis Aligned Crystalline IGZO is fine, and the oxygen defect is less, which can raise the stability of TFT; meanwhile, the area of the crystalline region in the manufactured C-axis Aligned Crystalline IGZO thin film is larger, which can promote the large scale application of the C-axis Aligned Crystalline IGZO.

Another objective of the present invention is to provide a C-axis Aligned Crystalline IGZO thin film. The crystalline quality of the C-axis Aligned Crystalline IGZO is fine, and the oxygen defect is less, which can raise the stability of TFT, and meanwhile the area of the crystalline region is larger, which is advantageous for the large scale application of the C-axis Aligned Crystalline IGZO.

For realizing the aforesaid objectives, the present invention provides a manufacture method of a C-axis Aligned Crystalline IGZO thin film, comprising steps of:

step 1, providing a substrate and an atomic layer deposition apparatus, and conveying the substrate into the atomic layer deposition apparatus, and introducing an indium oxide precursor material into the atomic layer deposition apparatus, and meanwhile, introducing a mixed gas of oxygen and inactive gas to form an indium oxide film on the substrate;

step 2, introducing cleaning gas into the atomic layer deposition apparatus to expel the indium oxide precursor material redundant in the atomic layer deposition apparatus to clean the atomic layer deposition apparatus;

step 3, introducing a gallium oxide precursor material into the atomic layer deposition apparatus, and meanwhile, introducing the mixed gas of oxygen and inactive gas to form a gallium oxide film on the indium oxide film;

step 4, introducing cleaning gas into the atomic layer deposition apparatus to expel the gallium oxide precursor material redundant in the atomic layer deposition apparatus to clean the atomic layer deposition apparatus;

step 5, introducing a zinc oxide precursor material into the atomic layer deposition apparatus, and meanwhile, introducing the mixed gas of oxygen and inactive gas to form a zinc oxide film on the gallium oxide film;

step 6, introducing cleaning gas into the atomic layer deposition apparatus to expel the zinc oxide precursor material redundant in the atomic layer deposition apparatus to clean the atomic layer deposition apparatus;

after step 1 to step 6, forming a layer of the C-axis Aligned Crystalline IGZO film on the substrate, and the C-axis Aligned Crystalline IGZO film comprising the indium oxide film, the gallium oxide film and the zinc oxide film which are aligned in order in a C-axis direction;

step 7, forming the C-axis Aligned Crystalline IGZO thin film on the substrate.

In step 7, step 1 to step 6 are repeated several times, and the C-axis Aligned Crystalline IGZO thin film comprises a plurality of C-axis Aligned Crystalline IGZO films which are stacked up, and a layer amount of the C-axis Aligned Crystalline IGZO films and times of repeating step 1 to step 6 are the same.

In step 1, the indium oxide precursor material comprises indium chloride and water.

In step 3, the gallium oxide precursor material comprises trimethyl gallium and water.

In step 5, the zinc oxide precursor material comprises diethyl zinc and hydrogen peroxide.

In step 1, step 3 and step 5, a temperature in the atomic layer deposition apparatus is controlled to be 310° C.-335° C., and a pressure is 5 mTorr-8 mTorr, and an operating power of the atomic layer deposition apparatus is 180W-200W; in the mixed gas of oxygen and inactive gas, an oxygen concentration is 15v %-17 v %.

In step 1, step 3 and step 5, the temperature in the atomic layer deposition apparatus is controlled to be 320° C., and the pressure is 7 mTorr, and the operating power of the atomic layer deposition apparatus is 190 W; in the mixed gas of oxygen and inactive gas, the oxygen concentration is 16v %.

In step 1, step 3 and step 5, in the mixed gas of oxygen and inactive gas, the inactive gas is argon.

In step 2, step 4 and step 6, the cleaning gas is nitrogen or inactive gas.

The present invention further provides a C-axis Aligned Crystalline IGZO thin film, comprising several layers of C-axis Aligned Crystalline IGZO films, and the C-axis Aligned Crystalline IGZO film comprises the indium oxide film, the gallium oxide film and the zinc oxide film which are aligned in order in a C-axis direction.

The present invention further provides a manufacture method of a C-axis Aligned Crystalline IGZO thin film, comprising steps of:

step 1, providing a substrate and an atomic layer deposition apparatus, and conveying the substrate into the atomic layer deposition apparatus, and introducing an indium oxide precursor material into the atomic layer deposition apparatus, and meanwhile, introducing a mixed gas of oxygen and inactive gas to form an indium oxide film on the substrate;

step 2, introducing cleaning gas into the atomic layer deposition apparatus to expel the indium oxide precursor material redundant in the atomic layer deposition apparatus to clean the atomic layer deposition apparatus;

step 3, introducing a gallium oxide precursor material into the atomic layer deposition apparatus, and meanwhile, introducing the mixed gas of oxygen and inactive gas to form a gallium oxide film on the indium oxide film;

step 4, introducing cleaning gas into the atomic layer deposition apparatus to expel the gallium oxide precursor material redundant in the atomic layer deposition apparatus to clean the atomic layer deposition apparatus;

step 5, introducing a zinc oxide precursor material into the atomic layer deposition apparatus, and meanwhile, introducing the mixed gas of oxygen and inactive gas to form a zinc oxide film on the gallium oxide film;

step 6, introducing cleaning gas into the atomic layer deposition apparatus to expel the zinc oxide precursor material redundant in the atomic layer deposition apparatus to clean the atomic layer deposition apparatus;

after step 1 to step 6, forming a layer of the C-axis Aligned Crystalline IGZO film on the substrate, and the C-axis Aligned Crystalline IGZO film comprising the indium oxide film, the gallium oxide film and the zinc oxide film which are aligned in order in a C-axis direction;

step 7, forming the C-axis Aligned Crystalline IGZO thin film on the substrate;

wherein in step 1, the indium oxide precursor material comprises indium chloride and water;

wherein in step 3, the gallium oxide precursor material comprises trimethyl gallium and water.

The benefits of the present invention are: the present invention provides a manufacture method of the C-axis Aligned Crystalline IGZO thin film. By utilizing the method of atomic layer deposition to manufacture the C-axis Aligned Crystalline IGZO thin film, the structure of the C-axis Aligned Crystalline IGZO can be accurately controlled in the atomic level, and the crystalline quality of the C-axis Aligned Crystalline IGZO is fine, and the oxygen defect is less, which can raise the stability of TFT; moreover, the area of the crystalline region in the C-axis Aligned Crystalline IGZO thin film manufactured by the present invention is larger, which reaches up for micron to millimeter level, and thus can promote the large scale application of the C-axis Aligned Crystalline IGZO; meanwhile, the present invention utilizes the optimized process condition to manufacture the C-axis Aligned Crystalline IGZO thin film, and the production yield can be raised and the production cost can be decreased. The present invention provides a C-axis Aligned Crystalline IGZO thin film. The crystalline quality of the C-axis Aligned Crystalline IGZO is fine, and the oxygen defect is less, which can raise the stability of TFT, and meanwhile the area of the crystalline region is larger, which is advantageous for the large scale application of the C-axis Aligned Crystalline IGZO.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a flowchart of a manufacture method of a C-axis Aligned Crystalline IGZO thin film according to the present invention;

FIG. 2 is a diagram of step 1 of the manufacture method of the C-axis Aligned Crystalline IGZO thin film according to the present invention;

FIG. 3 is a diagram of step 3 of the manufacture method of the C-axis Aligned Crystalline IGZO thin film according to the present invention;

FIG. 4 is a diagram of step 5 of the manufacture method of the C-axis Aligned Crystalline IGZO thin film according to the present invention;

FIG. 5 is a diagram of step 7 of the manufacture method of the C-axis Aligned Crystalline IGZO thin film according to the present invention and also a structure diagram of the C-axis Aligned Crystalline IGZO thin film according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

Atomic Layer Deposition (ALD) is a method of pulse alternately introducing the gas precursor into the reactor to form a deposition film on a substrate by chemical adsorption and reaction. When the precursors reach the surface of the substrate, they will have chemical adsorption on the surface and have the surface reaction. Between the precursor pulses, it is required to clean the atomic layer deposition reactor with the inactive gas. Obviously, whether the precursor material of the deposition reaction can be chemical adsorbed by the surface of the deposition material is the key to realize the atomic layer deposition. It can be seen from the adsorption characteristics of the gas phase material on the surface of the substrate, any gas phase material can conduct the physical adsorption. However, for realizing the chemical adsorption on the surface of the material, it must have certain activation energy. Therefore, it is very important to select proper precursor for deciding whether the atomic layer deposition can be realized.

The present invention utilizes the method of atomic layer deposition to manufacture the C-axis Aligned Crystalline IGZO. By having reaction of the proper precursor on the surface of the substrate and depositing and crystallizing the same according to the atomic layer order aligned in C-Axis, a C-axis Aligned Crystalline IGZO thin film of a larger area is formed on the substrate after n times repeat.

In the process of utilizing the method of the atomic layer deposition to conduct the deposition of the C-axis Aligned Crystalline IGZO thin film, the deposition temperature, the O₂ concentration, the deposition power and the working pressure are four crucial and important factors. For ensuring the best deposition condition of the C-axis Aligned Crystalline IGZO thin film, the present invention conducts the DOE experiment design for design the experiment of four factors and three levels. The design is within a certain range according to the three implementation values, the low level, the medium level and the high level to determine the relativity of the experiment parameters and the experiment results. The implementation values of the 4 factors and 3 levels of the designed DOE orthogonal experiment are shown in Table 1, and the specific implement plan of the DOE orthogonal experiment is shown in Table 2.

TABLE 1
implementation values of 4 factors and 3 levels of
DOE experiment design

| | | | medium | high |
|---|---|---|---|---|
| factor | unit | low level (1) | level (2) | level (3) |
| deposition temperature (A) | ° C. | 210 | 270 | 330 |
| oxygen concentration (B) | % | 5 | 10 | 20 |
| deposition power (C) | W | 50 | 100 | 200 |
| working pressure (D) | mTorr | 2 | 5 | 8 |

TABLE 2
specific implement plan of DOE experiment design

Column

| test number | A | B | C | D |
|---|---|---|---|---|
| 1 | 1 | 1 | 1 | 1 |
| 2 | 1 | 2 | 2 | 2 |
| 3 | 1 | 3 | 3 | 3 |
| 4 | 2 | 1 | 2 | 3 |
| 5 | 2 | 2 | 3 | 1 |
| 6 | 2 | 3 | 1 | 2 |
| 7 | 3 | 1 | 3 | 2 |
| 8 | 3 | 2 | 1 | 3 |
| 9 | 3 | 3 | 2 | 1 |

In the Table 2, A, B, C, D respectively mean the four factors, the deposition temperature (A), the oxygen concentration (B), the deposition power (C) and the working pressure (D) in the table 1. The Arabic numerals 1, 2, 3 except the test number respectively mean the experimental values of the low level (1), the medium level (2) and high level (3) in the table 1.

With the aforesaid DOE experiment, the optimized deposition process parameters of the C-axis Aligned Crystalline IGZO thin film which are finally obtained are: the deposition temperature is 310° C.-335° C., and the oxygen concentration is 15v %-17v %, and the working pressure is 5 mTorr-8 mTorr, and the deposition power is 180 W-200 W, and under the condition of the process, the area of the crystalline region of the C-axis Aligned Crystalline IGZO thin film manufactured by the method of the atomic deposition is larger, and the crystalline quality of the crystalline region is better, and thus, the production yield can be raised and the production cost can be decreased.

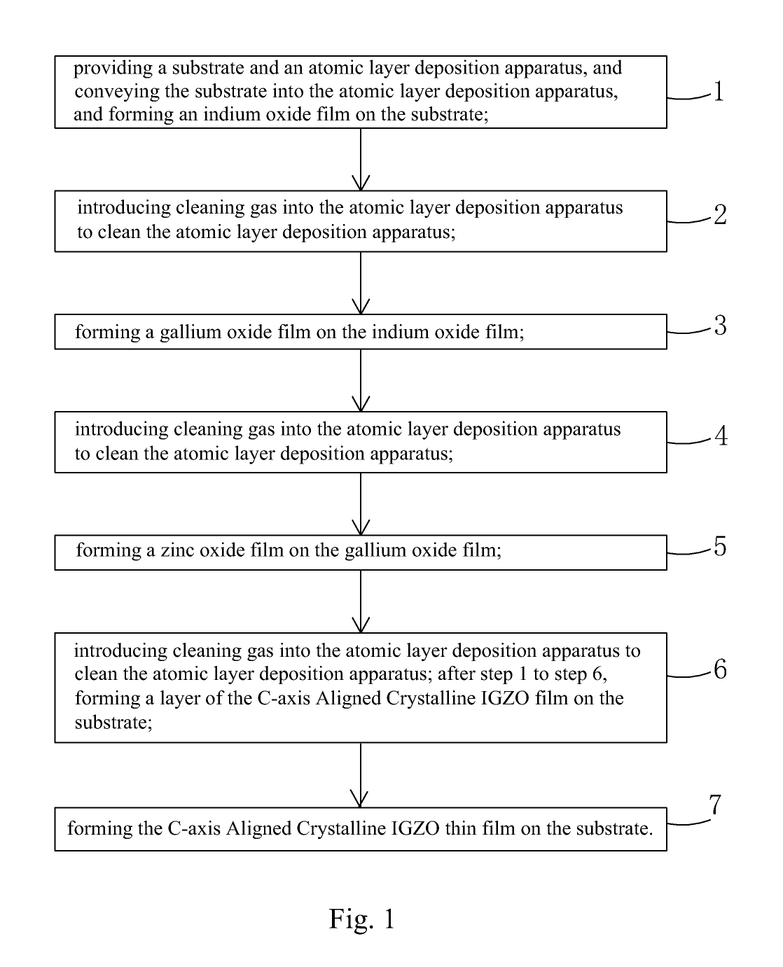

Please refer to FIG. 1. On the basis of the aforesaid DOE experiment result, the present invention provides a manufacture method of a C-axis Aligned Crystalline IGZO thin film, comprising steps of:

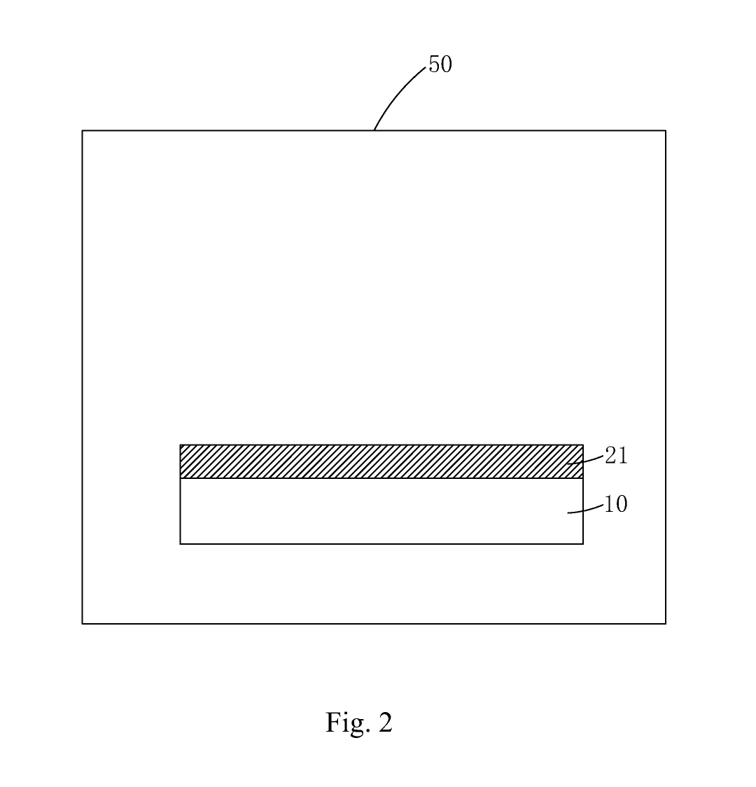

step 1, as shown in FIG. 2, providing a substrate 10 and an atomic layer deposition apparatus 50, and conveying the substrate 10 into the atomic layer deposition apparatus 50, and introducing an indium oxide precursor material into the atomic layer deposition apparatus 50, and meanwhile, introducing a mixed gas of oxygen and inactive gas to form an indium oxide (In₂O₃) film 20 on the substrate 10;

step 2, introducing cleaning gas into the atomic layer deposition apparatus 50 to expel the indium oxide precursor material redundant in the atomic layer deposition apparatus 50 to clean the atomic layer deposition apparatus 50;

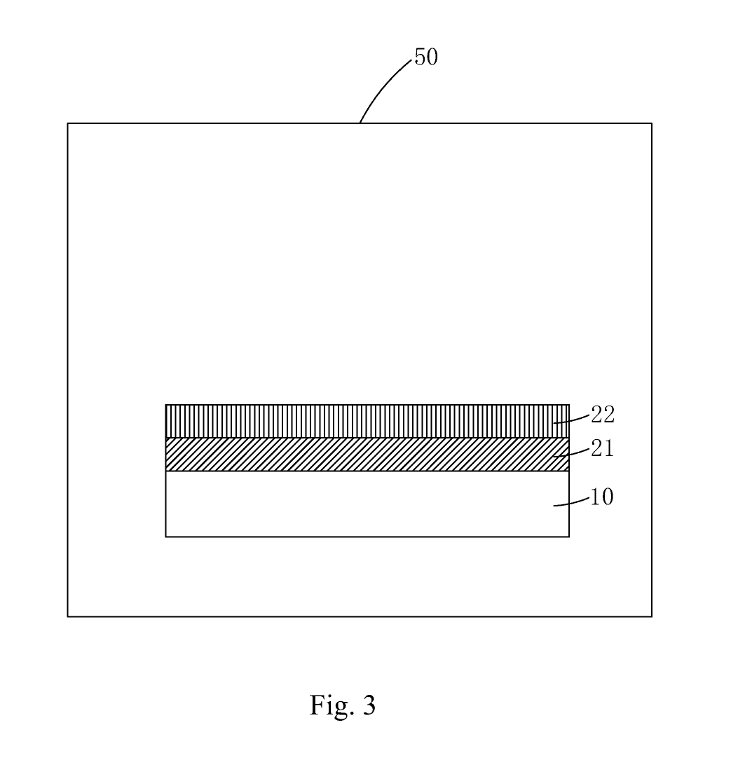

step 3, as shown in FIG. 3, introducing a gallium oxide precursor material into the atomic layer deposition apparatus 50, and meanwhile, introducing the mixed gas of oxygen and inactive gas to form a gallium oxide (Ga₂O₃) film 22 on the indium oxide film 21;

step 4, introducing cleaning gas into the atomic layer deposition apparatus 50 to expel the gallium oxide precursor material redundant in the atomic layer deposition apparatus 50 to clean the atomic layer deposition apparatus 50;

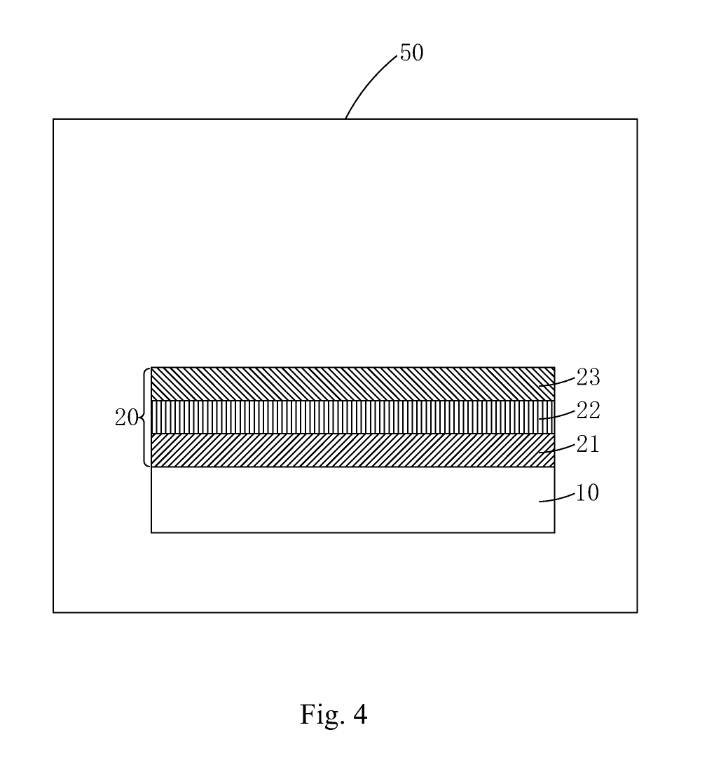

step 5, as shown in FIG. 4, introducing a zinc oxide precursor material into the atomic layer deposition apparatus 50, and meanwhile, introducing the mixed gas of oxygen and inactive gas to form a zinc oxide (ZnO) film 23 on the gallium oxide film 22;

step 6, introducing cleaning gas into the atomic layer deposition apparatus 50 to expel the zinc oxide precursor material redundant in the atomic layer deposition apparatus 50 to clean the atomic layer deposition apparatus 50;

after step 1 to step 6, forming a layer of the C-axis Aligned Crystalline IGZO film 20 on the substrate 10, and the C-axis Aligned Crystalline IGZO film 20 comprising the indium oxide film 21, the gallium oxide film 22 and the zinc oxide film 23 which are aligned in order in a C-axis direction;

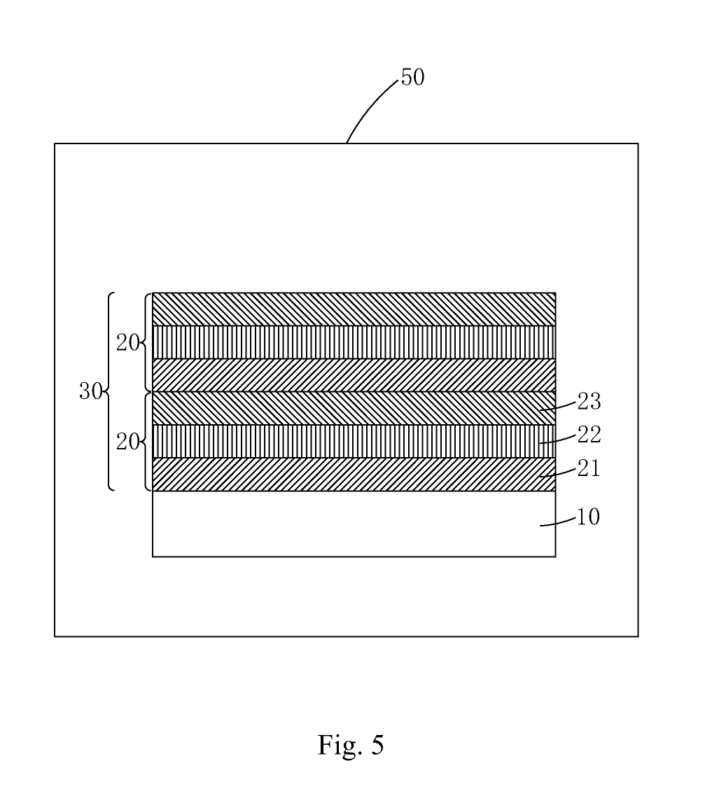

step 7, as shown in FIG. 5, forming the C-axis Aligned Crystalline IGZO thin film 30 on the substrate 10.

Specifically, in step 7, step 1 to step 6 are repeated several times, and the C-axis Aligned Crystalline IGZO thin film 30 comprises a plurality of C-axis Aligned Crystalline IGZO films 20 which are stacked up, and a layer amount of the C-axis Aligned Crystalline IGZO films 20 and times of repeating step 1 to step 6 are the same.

FIG. 5 is a structure diagram of the C-axis Aligned Crystalline IGZO thin film 30 manufactured in step 7. As shown in FIG. 5, the C-axis Aligned Crystalline IGZO thin film 30 comprises several layers of the C-axis Aligned Crystalline IGZO films 20, and each of the C-axis Aligned Crystalline IGZO films 20 comprises the indium oxide film 21, the gallium oxide film 22 and the zinc oxide film 23 which are aligned in order in a C-axis direction.

Specifically, in step 1, the indium oxide precursor material comprises indium chloride (Cl₃In) and water (H₂O).

Specifically, in step 3, the gallium oxide precursor material comprises trimethyl gallium ((CH₃)₃Ga) and water (H₂O).

Specifically, in step 5, the zinc oxide precursor material comprises diethyl zinc (Zn(C₂H₅)₂) and hydrogen peroxide (H₂O₂).

Preferably, in step 1, step 3 and step 5, a temperature in the atomic layer deposition apparatus 50 is controlled to be 310° C.-335° C., and a pressure is 5 mTorr-8 mTorr, and an operating power of the atomic layer deposition apparatus 50 is 180 W-200 W; in the mixed gas of oxygen and inactive gas, an oxygen concentration is 15v %-17v %.

Preferably, in step 1, step 3 and step 5, the temperature in the atomic layer deposition apparatus 50 is controlled to be 320° C., and the pressure is 7 mTorr, and the operating power of the atomic layer deposition apparatus 50 is 190 W; in the mixed gas of oxygen and inactive gas, the oxygen concentration is 16v %.

Specifically, in step 1, step 3 and step 5, in the mixed gas of oxygen and inactive gas, the inactive gas is argon.

Specifically, in step 1, step 3 and step 5, by introducing the mixed gas of oxygen and inactive gas into the atomic layer deposition apparatus 50, the oxygen atoms in the oxygen are used to fill the oxygen defects in the manufactured the indium oxide film 21, the gallium oxide film 22 and the zinc oxide film 23 to decrease the oxygen defects in the ultimately made C-axis Aligned Crystalline IGZO thin film 30 to promote the crystalline quality of the C-axis Aligned Crystalline IGZO thin film 30.

Specifically, in step 2, step 4 and step 6, the cleaning gas is nitrogen or inactive gas, and the inactive gas is preferably to be argon.

Specifically, the area of the crystalline region in the C-axis Aligned Crystalline IGZO thin film 30 manufactured by the present invention can reach up for micron level to millimeter level. In comparison with the manufacture process of the C-axis Aligned Crystalline IGZO thin film according to prior art, the area of the crystalline region in the C-axis Aligned Crystalline IGZO thin film 30 manufactured by the present invention is much larger, which can promote the large scale application of the C-axis Aligned Crystalline IGZO.

In general, the area of the crystalline region in the C-axis Aligned Crystalline IGZO thin film 30 manufactured in step 7 is 100 μm²-50 mm².

In general, the times of repeating step 1 to step 6 in step 7 are 100-200. The thickness of the C-axis Aligned Crystalline IGZO thin film 30 manufactured in step 7 can reach up to 100 nm-200 nm.

In the aforesaid manufacture method of the C-axis Aligned Crystalline IGZO thin film, by utilizing the method of atomic layer deposition to manufacture the C-axis Aligned Crystalline IGZO thin film, the structure of the C-axis Aligned Crystalline IGZO can be accurately controlled in the atomic level, and the crystalline quality of the C-axis Aligned Crystalline IGZO is fine, and the oxygen defect is less, which can raise the stability of TFT; moreover, the area of the crystalline region in the C-axis Aligned Crystalline IGZO thin film manufactured by the present invention is larger, which reaches up for micron to millimeter level, and thus can promote the large scale application of the C-axis Aligned Crystalline IGZO; meanwhile, the present invention utilizes the optimized process condition to manufacture the C-axis Aligned Crystalline IGZO thin film, and the production yield can be raised and the production cost can be decreased.

Please refer to FIG. 5. On the basis of the aforesaid manufacture method of the C-axis Aligned Crystalline IGZO thin film, the present invention further provides a C-axis Aligned Crystalline IGZO thin film, comprising several layers of C-axis Aligned Crystalline IGZO films 20 which are stacked up, and the C-axis Aligned Crystalline IGZO film 20 comprises the indium oxide film 21, the gallium oxide film 22 and the zinc oxide film 23 which are aligned in order in a C-axis direction.

Specifically, the foregoing several layers can be at least one layer.

Specifically, the area of the crystalline region in the C-axis Aligned Crystalline IGZO thin film is 100 μm²-50 mm².

Specifically, the thickness of the C-axis Aligned Crystalline IGZO thin film is 100 nm-200 nm.

In the aforesaid C-axis Aligned Crystalline IGZO thin film, the crystalline quality of the C-axis Aligned Crystalline IGZO is fine, and the oxygen defect is less, which can raise the stability of TFT, and meanwhile the area of the crystalline region is larger, which is advantageous for the large scale application of the C-axis Aligned Crystalline IGZO.

In conclusion, the present invention provides a C-axis Aligned Crystalline IGZO thin film and a manufacture method thereof. In the manufacture method of the C-axis Aligned Crystalline IGZO thin film of the present invention, by utilizing the method of atomic layer deposition to manufacture the C-axis Aligned Crystalline IGZO thin film, the structure of the C-axis Aligned Crystalline IGZO can be accurately controlled in the atomic level, and the crystalline quality of the C-axis Aligned Crystalline IGZO is fine, and the oxygen defect is less, which can raise the stability of TFT; moreover, the area of the crystalline region in the C-axis Aligned Crystalline IGZO thin film manufactured by the present invention is larger, which reaches up for micron to millimeter level, and thus can promote the large scale application of the C-axis Aligned Crystalline IGZO; meanwhile, the present invention utilizes the optimized process condition to manufacture the C-axis Aligned Crystalline IGZO thin film, and the production yield can be raised and the production cost can be decreased. In the C-axis Aligned Crystalline IGZO thin film of the present invention, the crystalline quality of the C-axis Aligned Crystalline IGZO is fine, and the oxygen defect is less, which can raise the stability of TFT, and meanwhile the area of the crystalline region is larger, which is advantageous for the large scale application of the C-axis Aligned Crystalline IGZO.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of a C-axis Aligned Crystalline IGZO thin film, comprising steps of:
step 1, providing a substrate and an atomic layer deposition apparatus, and conveying the substrate into the atomic layer deposition apparatus, and introducing an indium oxide precursor material into the atomic layer deposition apparatus, and meanwhile, introducing a mixed gas of oxygen and inactive gas to form an indium oxide film on the substrate;
step 2, introducing cleaning gas into the atomic layer deposition apparatus to expel the indium oxide precursor material redundant in the atomic layer deposition apparatus to clean the atomic layer deposition apparatus;
step 3, introducing a gallium oxide precursor material into the atomic layer deposition apparatus, and meanwhile, introducing the mixed gas of oxygen and inactive gas to form a gallium oxide film on the indium oxide film;
step 4, introducing cleaning gas into the atomic layer deposition apparatus to expel the gallium oxide precursor material redundant in the atomic layer deposition apparatus to clean the atomic layer deposition apparatus;
step 5, introducing a zinc oxide precursor material into the atomic layer deposition apparatus, and meanwhile, introducing the mixed gas of oxygen and inactive gas to form a zinc oxide film on the gallium oxide film;
step 6, introducing cleaning gas into the atomic layer deposition apparatus to expel the zinc oxide precursor material redundant in the atomic layer deposition apparatus to clean the atomic layer deposition apparatus;
after step 1 to step 6, forming a layer of the C-axis Aligned Crystalline IGZO film on the substrate, and the C-axis Aligned Crystalline IGZO film comprising the indium oxide film, the gallium oxide film and the zinc oxide film which are aligned in order in a C-axis direction;
step 7, forming the C-axis Aligned Crystalline IGZO thin film on the substrate.

2. The manufacture method of the C-axis Aligned Crystalline IGZO thin film according to claim 1, wherein in step 7, step 1 to step 6 are repeated several times, and the C-axis Aligned Crystalline IGZO thin film comprises a plurality of C-axis Aligned Crystalline IGZO films which are stacked up, and a layer amount of the C-axis Aligned Crystalline IGZO films and times of repeating step 1 to step 6 are the same.

3. The manufacture method of the C-axis Aligned Crystalline IGZO thin film according to claim 1, wherein in step 1, the indium oxide precursor material comprises indium chloride and water.

4. The manufacture method of the C-axis Aligned Crystalline IGZO thin film according to claim 1, wherein in step 3, the gallium oxide precursor material comprises trimethyl gallium and water.

5. The manufacture method of the C-axis Aligned Crystalline IGZO thin film according to claim 1, wherein in step 5, the zinc oxide precursor material comprises diethyl zinc and hydrogen peroxide.

6. The manufacture method of the C-axis Aligned Crystalline IGZO thin film according to claim 1, wherein in step 1, step 3 and step 5, a temperature in the atomic layer deposition apparatus is controlled to be 310° C.-335° C., and a pressure is 5 mTorr-8 mTorr, and an operating power of the atomic layer deposition apparatus is 180 W-200 W; in the mixed gas of oxygen and inactive gas, an oxygen concentration is 15v %-17v %.

7. The manufacture method of the C-axis Aligned Crystalline IGZO thin film according to claim 6, wherein in step 1, step 3 and step 5, the temperature in the atomic layer deposition apparatus is controlled to be 320° C., and the pressure is 7 mTorr, and the operating power of the atomic layer deposition apparatus is 190 W; in the mixed gas of oxygen and inactive gas, the oxygen concentration is 16v %.

8. The manufacture method of the C-axis Aligned Crystalline IGZO thin film according to claim 1, wherein in step 1, step 3 and step 5, in the mixed gas of oxygen and inactive gas, the inactive gas is argon.

9. The manufacture method of the C-axis Aligned Crystalline IGZO thin film according to claim 1, wherein in step 2, step 4 and step 6, the cleaning gas is nitrogen or inactive gas.

10. A C-axis Aligned Crystalline IGZO thin film, comprising several layers of the C-axis Aligned Crystalline IGZO films, and the C-axis Aligned Crystalline IGZO film comprising the indium oxide film, the gallium oxide film and the zinc oxide film which are aligned in order in a C-axis direction.

11. A manufacture method of a C-axis Aligned Crystalline IGZO thin film, comprising steps of:
step 1, providing a substrate and an atomic layer deposition apparatus, and conveying the substrate into the atomic layer deposition apparatus, and introducing an indium oxide precursor material into the atomic layer deposition apparatus, and meanwhile, introducing a mixed gas of oxygen and inactive gas to form an indium oxide film on the substrate;
step 2, introducing cleaning gas into the atomic layer deposition apparatus to expel the indium oxide precursor material redundant in the atomic layer deposition apparatus to clean the atomic layer deposition apparatus;
step 3, introducing a gallium oxide precursor material into the atomic layer deposition apparatus, and meanwhile, introducing the mixed gas of oxygen and inactive gas to form a gallium oxide film on the indium oxide film;
step 4, introducing cleaning gas into the atomic layer deposition apparatus to expel the gallium oxide precursor material redundant in the atomic layer deposition apparatus to clean the atomic layer deposition apparatus;
step 5, introducing a zinc oxide precursor material into the atomic layer deposition apparatus, and meanwhile, introducing the mixed gas of oxygen and inactive gas to form a zinc oxide film on the gallium oxide film;
step 6, introducing cleaning gas into the atomic layer deposition apparatus to expel the zinc oxide precursor material redundant in the atomic layer deposition apparatus to clean the atomic layer deposition apparatus;
after step 1 to step 6, forming a layer of the C-axis Aligned Crystalline IGZO film on the substrate, and the C-axis Aligned Crystalline IGZO film comprising the indium oxide film, the gallium oxide film and the zinc oxide film which are aligned in order in a C-axis direction;
step 7, forming the C-axis Aligned Crystalline IGZO thin film on the substrate;
wherein in step 1, the indium oxide precursor material comprises indium chloride and water;
wherein in step 3, the gallium oxide precursor material comprises trimethyl gallium and water.

12. The manufacture method of the C-axis Aligned Crystalline IGZO thin film according to claim 11, wherein in step 7, step 1 to step 6 are repeated several times, and the C-axis Aligned Crystalline IGZO film comprises a plurality of C-axis Aligned Crystalline IGZO films which are stacked up, and a layer amount of the C-axis Aligned Crystalline IGZO films and times of repeating step 1 to step 6 are the same.

13. The manufacture method of the C-axis Aligned Crystalline IGZO thin film according to claim 11, wherein in step 5, the zinc oxide precursor material comprises diethyl zinc and hydrogen peroxide.

14. The manufacture method of the C-axis Aligned Crystalline IGZO thin film according to claim 11, wherein in step 1, step 3 and step 5, a temperature in the atomic layer deposition apparatus is controlled to be 310° C.-335° C., and a pressure is 5 mTorr-8 mTorr, and an operating power of the atomic layer deposition apparatus is 180 W-200 W; in the mixed gas of oxygen and inactive gas, an oxygen concentration is 15v %-17v %.

15. The manufacture method of the C-axis Aligned Crystalline IGZO thin film according to claim 14, wherein in step 1, step 3 and step 5, the temperature in the atomic layer deposition apparatus is controlled to be 320° C., and the pressure is 7 mTorr, and the operating power of the atomic layer deposition apparatus is 190 W; in the mixed gas of oxygen and inactive gas, the oxygen concentration is 16v %.

16. The manufacture method of the C-axis Aligned Crystalline IGZO thin film according to claim 11, wherein in step 1, step 3 and step 5, in the mixed gas of oxygen and inactive gas, the inactive gas is argon.

17. The manufacture method of the C-axis Aligned Crystalline IGZO thin film according to claim 11, wherein in step 2, step 4 and step 6, the cleaning gas is nitrogen or inactive gas.
